(19) United States
(12) Patent Application Publication
(10) Pub. No.: US 2026/0140180 A1
(43) Pub. Date: May 21, 2026

(54) SYSTEM AND METHOD FOR DETERMINING AN OPERATIONAL STATUS OF A CONTACTOR IN AN ELECTRIC VEHICLE

(71) Applicant: BOMBARDIER RECREATIONAL PRODUCTS INC., Valcourt (CA)

(72) Inventors: Cong-Long NGUYEN, Sherbrooke (CA); Jasmin ROULEAU, Waterville (CA)

(21) Appl. No.: 19/395,338

(22) Filed: Nov. 20, 2025

Related U.S. Application Data
(60) Provisional application No. 63/723,278, filed on Nov. 21, 2024.

(51) Int. Cl. G01R 31/327; B60L 3/00; G07C 5/08

(52) U.S. Cl. CPC G01R 31/3274; B60L 3/0046; G01R 31/3275; G07C 5/0808; G07C 5/0816

(57) ABSTRACT

A system and method for determining the operational status of a contactor that connects/disconnects an electric vehicle (EV) traction power circuit to a high voltage (HV) battery, is presented. The system includes a contactor test circuit that incorporates a test switch coupled to a terminal of the HV battery and a sensor which forms a series circuit with the contactor to be tested for detecting a current flow. The system further includes a controller coupled to the test switch, the contactor, and the sensor in which the controller is configured to: receive an expected state of the contactor, close the test switch to detect whether current flows through the sensor, identify the observed contactor state; open the test switch, and compare the expected and observed states of the contactor. Upon a mismatch between the expected and observed state of the contactor, the controller transmits a warning.

### CROSS-REFERENCE TO RELATED APPLICATIONS

The present application claims priority to U.S. Provisional Ser. No. 63/723,278 , entitled “System and Method for Determining an Operational Status of s Contactor in an Electric Vehicle,” filed Nov. 21, 2024, the entirety of which is incorporated by reference herein.

### FIELD OF TECHNOLOGY

The present technology relates to power switching circuits of electric vehicles and, in particular, to the determination of an operational status of a contactor.

### BACKGROUND

The trend towards the electrification of road vehicles has also impacted powersport vehicles, such as, for example, motorcycles, snowmobiles, all-terrain vehicles, and personal watercrafts. As such, there are efforts to improve the performance, reliability, and safety of the electric power supplied to such electric vehicles (EVs), including the power supply switching circuits.

EVs typically employ a high voltage (HV) battery pack. Such battery packs are typically configured to 400V or 800V, but a voltage of 60V or more is generally considered to be high voltage for EVs. Due to the high voltage and corresponding high currents, the delivery of electrical power by the HV battery pack to the EV's traction power circuit is generally controlled by electromechanical contactors that are configured to handle high voltages/current present when opening and closing a connection of the HV battery pack to the EV traction power circuit. For example, as illustrated by the cross-sectional view of FIG. 1 (Prior Art), representative normally open contactor 100 comprises stationary contacts 102, movable contacts 104, armature 105, spring 106, electromagnet 107 and coil 108. With this configuration, upon energizing coil 108 to connect the HV battery pack to the EV traction power circuit, the armature 105 is attracted to the electromagnet 107 with sufficient force to overcome the tension of the springs 106 and the movable contacts 104 fixed to the armature 105 move and engage the stationary contacts 102.

During EV operations, the opening/closing of the power circuit connection to the voltage/current of the HV battery pack may occasionally result in electrical arcing. Usually, this arc manifests a low current and is quickly extinguished, as the contactors are typically enabled to open at a time when there is little current circulating through them, such as when the powertrain is turned off.

However, in certain situations, such as, for example, an emergency situation, the contactors may be opened while the vehicle is drawing maximal current from the battery, in this case, the arc created will have a much higher current. Intentionally creating an electrical arc between two metallic components is a well-known method for welding them together by partially melting them, the same phenomenon can unintentionally occur inside of the contactor 100. The arc could have sufficient current to, at least partially, weld the movable contacts 104 to the stationary contacts 102.

Additionally, electrical arcs often manifest very high voltages that can cause displacement of material between the contact surfaces 102, 104, for example through pitting of one contact surface and consequently deposition of this material elsewhere on another contact surface, as well as produce heat and carbon in the form of dust. Over time, the alterations to the surface of the contacts 102, 104 make their surface increasingly irregular, which can increase the resistance between them, generating excess heat and leading to a smaller specific surface area making or breaking contact with the opposing contact surface, increasing the probability and intensity of arcs occurring. This heat may also cause metallic components, such as the contacts themselves, to expand, making them harder to separate. The result of these effects is that the force of the spring 106 may become insufficient to separate the contactors contacts when the coil 108 is deenergized.

Additionally, the heat generated by repeated exposure to such high voltage arcing may also result in the deterioration of the mechanical components like spring 106 or coil 108. The deterioration of these components may compromise the ability of the contacts 104 to properly move upon actuation, causing significant issues with the closing/opening operations of the contactor 100.

The failure of contactors to function properly can have deleterious consequences to EV operations, as contactors are the principal components for opening/closing the EV traction power circuit between the HV battery pack power supply and the powertrain. It is known to run a testing sequence to check for welded or otherwise stuck contactors before sending the command to close them. This sequence typically involves closing and opening the contactors themselves, one at a time in rapid succession, while monitoring for the presence of voltage between the positive and negative sides of the powertrain circuit, at the load side. Since the contactors are each in series with the load (contactors on both sides of the circuit), when the expected state of all contactors is open, closing a single contactor should not cause voltage to be present at the powertrain circuit load. If voltage is detected, it can be deduced that the contactor which is expected to be open has become welded or stuck, completing the series circuit with the load.

However, there are downsides to this method of verifying the contactor state. Since the contactors are switched, this creates additional close/open cycles, which can reduce the operational life of the contactors. When the coil 108 is energized and deenergized, power is consumed reducing efficiency of the process. Additionally, individually switching each contactor takes some time, which can be an irritant when the sequence is required to be carried out at every vehicle startup and shutdown. Finally, in the situation where a contactor is unknowingly welded, closing the other serially connected contactor creates a situation where the powertrain circuit is effectively unintentionally energized, which is not desirable. Therefore, there exists interest in providing measures that verify proper functioning of the contactors.

### SUMMARY

The present technology is directed to providing measures for routinely confirming the proper functioning of switch contactors providing connectivity to an EV traction power circuit.

In accordance with an embodiment of the present technology, there is provided a system for determining an operational status of at least one contactor of an electric vehicle (EV), in which the at least one contactor is controllably movable between a closed state and an open state, the system including: an electric power source having a positive and a negative terminal; a contactor test circuit configured to determine the operational status of the at least one contactor, the contactor test circuit employing: at least one test switch electrically-coupled in series with the electric power source, the at least one contactor and at least one sensor, the at least one sensor configured to detect current flow passing therethrough; and a control unit operatively-coupled to the at least one test switch, the at least one contactor, and the at least one sensor. The control unit configured with executable instructions to: communicate with the at least one contactor to change its current state or receive a signal indicative of its current state; register an expected state of the at least one contactor, based on the control unit communication or the received signal; operate the at least one test switch, to detect whether current flows through the at least one sensor; receive a signal from the at least one sensor indicative of an observed state of the at least one contactor, based on whether current flows through the at least one sensor; and compare the expected state to the observed state.

A related aspect of the embodiment of the present technology, provides that the control unit is configured to: detect whether current flows through the at least one sensor, which indicates that the at least one contactor is in the closed state; and detect whether no current flows through the at least one sensor, which indicates that the at least one contactor is in the open state.

An additional aspect of the embodiment of the present technology, provides that, in response to the comparison indicating that the expected state and the observed state do not match, the control unit issues a warning.

In accordance with another embodiment of the present technology, there is provided a a method for determining an operational status of at least one contactor of an electric vehicle (EV), the at least one contactor being controllably movable between a closed state and an open state, wherein the EV includes: an electric power source with a positive and a negative terminal; a contactor test circuit configured to determine the operational status of the at least one contactor, in which the contactor test circuit includes: at least one test switch electrically-coupled in series with the electric power source, the at least one contactor and at least one sensor, the at least once sensor configured to detect current flow passing therethrough; and a control unit operatively-coupled to the at least one test switch. The control unit configured with executable instructions to implement the method comprising: communicating with the at least one contactor to change its current state or receive a signal indicative of its current state; registering, by the control unit, an expected state of the at least one contactor based on the control unit's communication or the received signal; operating, by the control unit, the at least one test switch to detect whether current flows through the at least one sensor; receiving, by the control unit, a signal from the at least one sensor indicative of an observed state of the at least one contactor based on whether current flows through the at least one sensor; and comparing, by the control unit, the expected state to the observed state.

A related aspect of the embodiment of the present technology, provides that the method is configured to detect whether current flows through the at least one sensor, which indicates that the at least one contactor is in the closed state; and detect whether no current flows through the at least one sensor, which indicates that the at least one contactor is in the open state.

An additional aspect of the embodiment of the present technology, provides that the method, in response to the comparison indicating that the expected state and the observed state do not match, issues a warning.

Within the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Furthermore, the use of the phrase “at least one of A and B” is intended to mean A only, B only or both A and B.

It should be understood that, unless otherwise explicitly specified herein, the drawings are not necessarily to scale. Moreover, the drawings may omit certain features or may exaggerate certain features in order to assist in the clear understanding of the disclosed embodiments.

Additional and/or alternative features, aspects and advantages of embodiments of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description that is to be used in conjunction with the accompanying drawings, in which:

FIG. 1 (Prior Art) illustrates a cross-sectional view of a representative contactor for an electric vehicle;

FIG. 2 illustrates a conceptual diagram of an electric vehicle power control system, in accordance with a non-limiting embodiment of the present technology;

FIG. 3A illustrates a representative circuit diagram for diagnostic testing of an electric vehicle's switch contactors, in accordance with a non-limiting embodiment of the present technology;

FIGS. 3B, 3C, 3D, 3E illustrate isolated views of the diagnostic testing circuit for each of the electric vehicle switch contactors, in accordance with a non-limiting embodiment of the present technology;

FIG. 4 illustrates a process for the diagnostic testing of an electric vehicle's switch contactors, in accordance with a non-limiting embodiment of the present technology; and

FIG. 5 illustrates an exemplary process of the diagnostic testing mode for contactors K1-K4, as enabled by the diagnostic testing circuit configuration, in accordance with the non-limiting embodiments of the present technology.

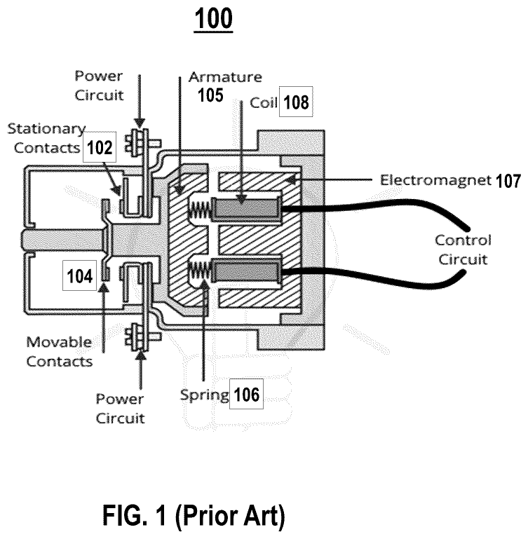

It should be noted that, unless otherwise explicitly specified herein, the drawings are not necessarily to scale.

### DETAILED DESCRIPTION

The present technology will be described herein with respect to an electric vehicle (EV) power supply switching circuit that connects/disconnects the EV powertrain to/from a high voltage (HV) battery pack. The EV power supply switching circuit and HV battery packs may be incorporated in a variety of electric vehicle types including, but not limited to, electric motorcycles, electric snowmobiles, electric all-terrain vehicles (ATVs), two-wheeled straddle-seat electric vehicles, three-wheeled electric vehicles, electric side-by-side vehicles, four-wheeled electric vehicles, and electric watercraft. It is contemplated that at least some aspects of the present technology may also be used in electric vehicles other than electric powersport vehicles.

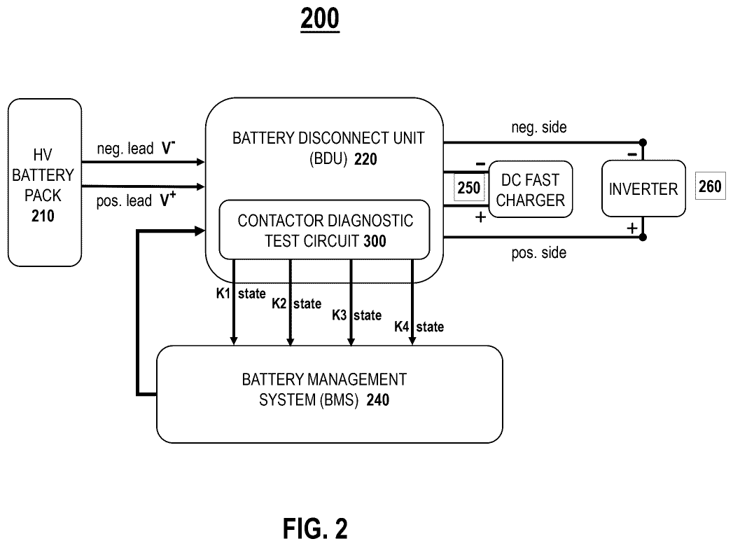

FIG. 2 depicts a conceptual diagram of an overall electric vehicle power control system 200, in accordance with a non-limiting embodiment of the present technology. As shown, system 200 comprises an HV battery pack 210, a battery disconnect unit (BDU) 220, a battery management system (BMS) 240, a contactor test circuit 300, DC fast charger 250, and inverter 260, which receives DC power and delivers three phase AC power to the motor (not shown).

The HV battery pack 210 supplies the power necessary for EV operations. As such, the HV battery pack 210 extends a lead connected to a negative terminal V⁻ of the HV battery and a lead connected to a positive terminal V⁺ of the HV battery pack 210 to convey the high voltage levels to the BDU 220.

The BDU 220 contains contactors, fuses, pre-charge circuits and current sensors to monitor, activate, and deactivate HV battery power supply as well as provide low DC voltages (e.g., 5V or 12V) to activate various electrical components. In particular, the BDU 220 includes circuitry that connects/disconnects the HV battery power supply to/from the EV traction power circuit and inverter 260 via high voltage/current contactors K1-K4.

As shown, the BDU 220 further includes a contactor test circuit 300 which, as discussed in greater detail below, tests the operational status of the main contactors K1-K2 involved in any vehicle operation requiring traction battery power and contactors K3-K4 specifically for DC fast charging port 250. Essentially, the testing of contactors K1-K4 involves initially determining whether the contactors K1-K4 are unexpectedly in a closed state (i.e., welded closed), then verifying their proper function, whether they properly close and open, upon being controlled to do so via energizing or deenergizing the coil 108, with a low activation voltage (e.g., 12V). The switching between closing/opening the contactors K1-K4 by energizing/de-energizing coil 108 is enabled by the BMS 240 control unit. In order to increase the probability of detecting an issue, the operational testing of contactors K1-K4 may be configured to occur at every EV startup, shutdown, or both.

The BMS 240 provides overall monitoring and control of the power flowing to/from the HV battery pack. BMS 240 employs a control unit (not shown) configured to evaluate numerous parameters and determine, among other things, the HV battery pack 210 health and charge status as well as control the BDU 220. Moreover, in accordance with the embodiments of the present technology, the BMS 240 control unit is also configured to enable the forwarding of a small activation voltage (e.g., 5V) to activate the contactor test circuit 300 at EV startup/shutdown as well as receive the observed status of contactors K1-K4 and provide status warnings and/or prevent closure of a detected malfunctioning contactor.

As such, the BMS 240 control unit is configured to register the “expected state” of contactors K1-K4 in view of the closing/opening control of contactors K1-K4, in accordance with the energizing/de-energizing of the contactor coils 108. As will be described in greater detail below, at EV startup, before the powertrain is energized or after shutdown, once the powertrain has been de-energized, the expected state of contactors K1-K4 is to be in the open state. The same is true when any of the contactors K1-K4 are controlled to be opened by the BMS 240 control unit, via commands to deenergize the contactor coils 108. Conversely, when any of the contactors K1-K4 are enabled to be closed by the BMS 240 control unit by energizing the contactor coils 108, the expected state of the corresponding contactors is the closed state.

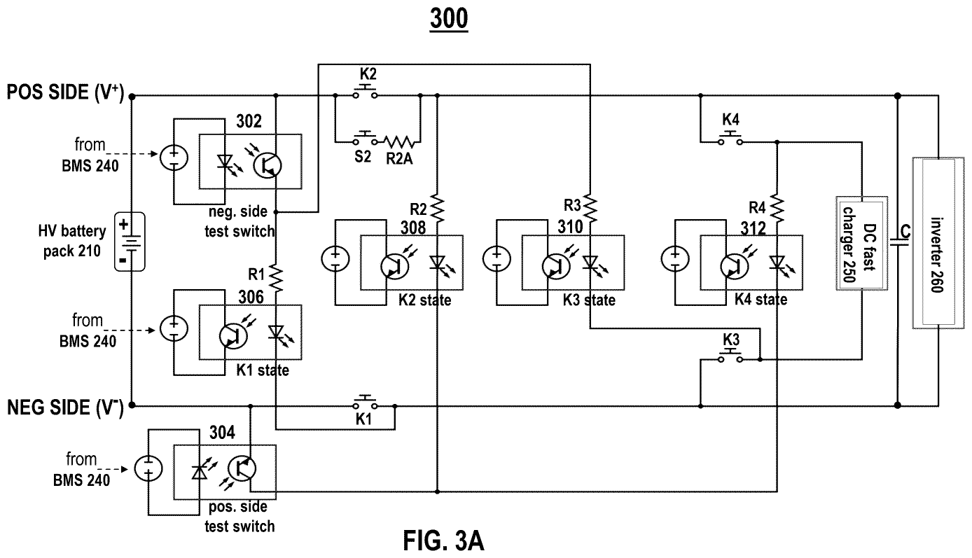

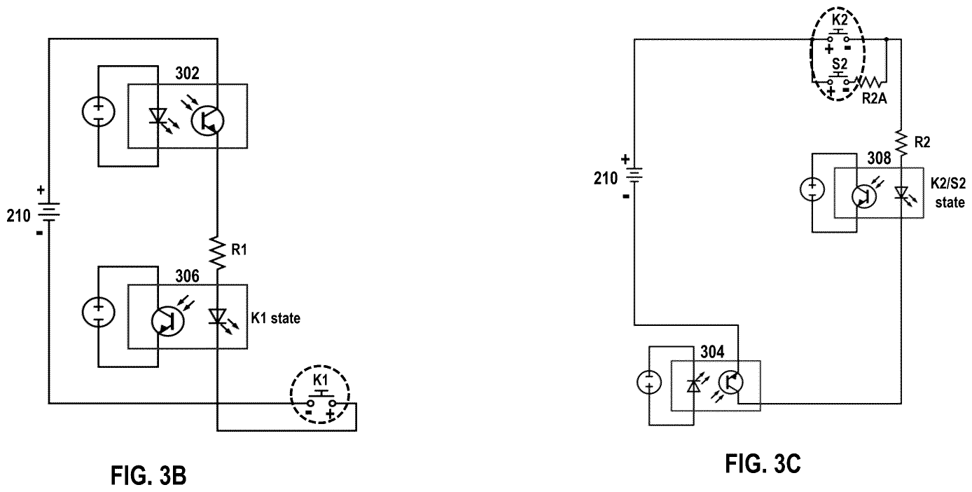

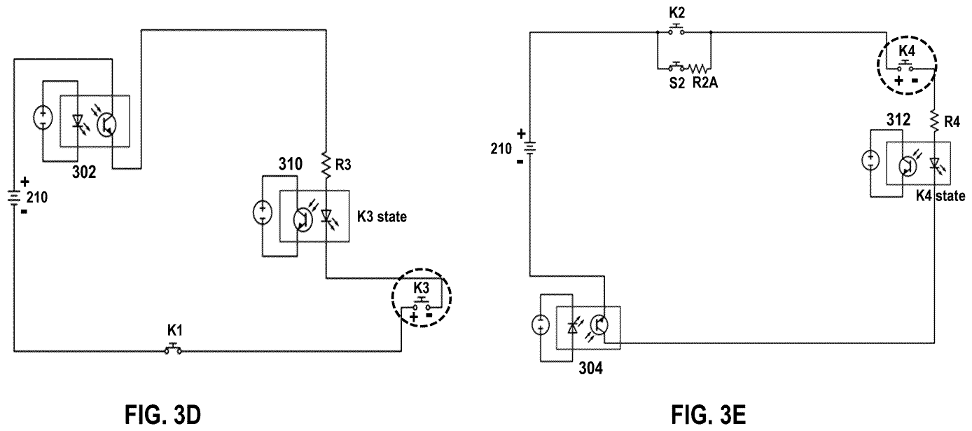

FIG. 3A depicts a diagram of representative contactor test circuit 300 for determining the operational status of the EV contactors K1-K4, in accordance with the non-limiting embodiments of the present technology. Moreover, in an effort to provide clarity and ease of understanding, FIGS. 3B, 3C, 3D, 3E illustrate respective isolated views of each of the electric vehicle contactors K1-K4 of the contactor test circuit 300, in accordance with a non-limiting embodiment of the present technology. FIGS. 3B, 3C, 3D, 3E each represent a circuit, which is effectively formed by switching certain components of test circuit 300, each of circuits 3B, 3C, 3D, 3E enabling the testing of one of contactors K1, K2 (and/or S2), K3, K4. It should, therefore, be understood that the following detailed descriptions of the contactor test circuit 300 will be based on the features depicted by the overall circuit 300 configuration of FIG. 3A, as well as the isolated views of the individual vehicle contactors K1-K4 depicted by FIGS. 3B-3E.

With this said, the operational status determination of contactors K1-K4 is directed to testing whether the contactors K1-K4 actually close/open after the test circuit 300 has been activated.

As shown, diagnostic testing circuit 300 is located in parallel to the traction power circuit, between the negative V⁻ and positive V⁺ terminals of the HV battery pack. Testing circuit 300 further comprises a negative side test switch 302, a positive side test switch 304, and sensors 306, 308, 310, 312 that are serially connected to the positive and negative battery terminals and the corresponding contactors K1-K4, when the diagnostic testing circuit 300 assumes the corresponding testing configuration, which will be described in greater detail below.

The sensors 306, 308, 310, 312 comprise diagnostic optocouplers to detect a current flowing therethrough which is indicative of the state of contactors K1-K4, as long as the corresponding negative side test switch 302 or positive side test switch 304 are closed. It will be appreciated, however, that the use of other suitable current detectors/sensors, such as, for example, Hall Effect current sensors, etc. have also been considered and contemplated by the present technology.

FIG. 3B shows the series circuit, comprising a portion of circuit 300, which is used to test negative side contactor K1 and FIG. 3C shows the series circuit, comprising another portion of circuit 300, used to test positive side contactors K2 and S2. In particular, detecting current flow through sensors 306, 308, indicates that the state of contactors K1-K2 (i.e., K1 state, K2 state, S2 state) which serve to open/close the powertrain and charger circuit (charger not shown) are in the “closed state”. The absence of detecting current flow through sensors 306, 308, indicates that the K1 state, K2 state and S2 state are in the “open state”.

FIG. 3D shows the series circuit, comprising yet another portion of circuit 300, which is used to test negative side contactor K3 and FIG. 3E shows the series circuit, comprising a fourth portion of circuit 300, used to test positive side contactors K4. Note that the testing of contactors K3 and K4 require contactors K1 and K2 (or S2) to be closed beforehand, since they are both part of their respective series circuits. Similarly, detecting current flow through sensors 310, 312, indicates that the state of contactors K3-K4 (i.e., K3 state, K4 state) for switching the circuit to DC fast charging is in the “closed state”. While the absence of detecting current flow through sensors 310, 312, indicates that the K3 state and K4 state are in the “open state”, assuming contactors K1-K2 are known to be closed.

In addition, testing circuit 300 is electrically connected to the DC fast charging port 250, capacitor C, and power inverter 260, which are all arranged in parallel between the negative and positive terminals V⁻, V⁺ of the HV battery. The capacitor C, otherwise known as a DC link capacitor, serves as a buffer to mitigate voltage fluctuations of the direct current being transferred to the load, typically the inverter, but the load could instead be the HV battery, during regenerative braking for example.

The negative and positive side test switches 302, 304 along with the sensors 306-312, require a small voltage (e.g., 5V) enabled by the BMS 240 control unit to be activated. The negative and positive side test switches 302, 304 incorporate an optocoupler-based switch operating as solid state contactors (SSCs) or solid state relays (SSRs). Upon being activated (i.e., receiving a small activation 5V voltage enabled by the BMS 240 control unit), the optocoupler-based switch turns on an internal LED, the light of which causes a phototransistor to switch on, i.e. become conductive, with both the LED and the phototransistor sections operating in a galvanically isolated manner. The sensors 306-312 also operate with both the LED and the phototransistor sections operating in a galvanically isolated manner, but in an opposite way to the test switches 302, 304.

Upon one of the corresponding test switches 302, 304 being closed, the sensor's internal LED will begin producing light if current from the HV battery is present in this branch of the testing circuit. The light generated by the sensor's LED makes the corresponding phototransistor conductive, which operates to indicate that current is present and that the corresponding series circuit shown in FIG. 3B, 3C, 3D or 3E is closed. The phototransistor in each of the sensors 306-312 is, for example, in series with a low voltage (e.g., 5V) circuit.

This low voltage circuit will not have a voltage or any current circulating therethrough (i.e. an open circuit) when there is no current from the HV battery present in the corresponding testing circuit of FIG. 3B, 3C, 3D or 3E to power the LED. The optocoupler-based test switches 302, 304 have the ability to operate substantially faster in terms of switching on/off than the contactors K1-K4, (e.g., a few milliseconds vs. up to one second) and do so more efficiently, since there is no coil to charge. As such, the verification of the state of the contactors K1-K4 can be performed without any noticeable delays observed by EV drivers and without performing additional opening/closing cycles of the contactors K1-K4 which reduces wear of the contactors K1-K4.

As discussed above, testing circuit 300 is electrically-connected to contactors K1-K2 that are to be closed for operations requiring HV battery power and to contactors K3-K4 that are to be closed to enable DC fast charging. It is noted that, positioned in parallel to contactor K2, is a pre-charging contactor S2 that is serially-connected to current-limiting resistor R2A. The pre-charging contactor S2 operates to mitigate an inrush current during the startup sequence, notably due to the charging of capacitor C. During a typical contactor closing sequence, performed at each vehicle startup, negative side contactor K1 is closed, then pre-charging contactor S2 is closed. If capacitor C or any other capacitance in the powertrain circuit is not fully charged (which may be the case when at least one of contactors K1 or K2 has been in the open state for some time), upon closing of S2, the testing circuit 300 will effectively be short-circuited, until capacitor C (or any other capacitance) is fully charged.

During the time required to charge capacitor C, a large amount of current draw that may generate a temporary short circuit is prevented by current limiting resistor R2A. Additionally, a high inrush current would be likely to generate a powerful electrical arc, while the contacts are approaching each other before they make contact, which may contribute to all the negative consequences of arcing inside a contactor. Once the capacitance has been sufficiently charged, positive side contactor K2 is closed and contactor S2 is then opened, effectively removing the current limiting resistor R2A from the powertrain circuit to allow the EV to operate efficiently.

With regard to the configuration of current-limiting resistors, each of the sensors 306, 308, 310, 312 are serially-connected to corresponding current-limiting resistors R1, R2, R3, R4 respectively, as shown in the circuits of FIGS. 3B, 3C, 3D and 3E. The current-limiting resistors R1, R2, R3, R4 operate to limit the current flow between the positive and negative terminals of the HV battery pack, which could otherwise damage the optocoupler switches 302, 304 and sensors 306, 308, 310, 312. Additionally, because the positive and negative test switches 302, 304 are transistor-based, they will conduct a small amount of leakage current through them even when they are switched off, which constitutes electrical losses. As such, current-limiting resistors R1-R4 operate to limit such electrical leak losses during normal EV use.

The electronic configuration of testing circuit 300 enables the execution of test sequences during a diagnostic testing mode of EV contactors. For example, in an exemplary test sequence, initiated upon vehicle startup, before an instruction to close any of the main or fast charge contactors K1-K4 is enabled by the BMS 240 control unit (i.e., no current provided to coils 108, so the “expected state” of all contactors K1-K4 is the “open state”), the LED of positive side test switch 304 is powered on (e.g., receives an activation 5V voltage). The light from the LED then shines on the phototransistor within the optocoupler switch 304 to make it conductive.

In the circuit depicted in FIG. 3C, if contactor K2 and S2 are in the “open state” (as expected), the sensor 308 of testing circuit 300 will not experience any voltage across it, therefore, the optocoupler 308 LED will not illuminate. Therefore, the phototransistor of sensor 308 is not conductive, which indicates an open circuit, which would imply that both contactor K2 and S2 are open. Because the expected state and the observed state of these contactors match, the BMS 240 control unit determines that the contactors K2 and S2 are operating properly.

However, if contactor K2 is unexpectedly in a closed state, due to welding or other component deterioration conditions, then an “unexpected” voltage across the test circuit shown in FIG. 3C will result, as the phototransistor of sensor 308 will receive light from the LED. This indicates improper status, which is detected by the BMS 240 control unit when the transistor of sensor 308 becomes conductive. In response, the BMS 240 control unit is configured to take appropriate action, such as, for example, sending a warning to the EV driver and/or disable or prevent the closure of any other contactor, to avoid causing further malfunction in circuit 300. It will be appreciated that the same result will also occur if pre-charging contactor S2 is welded or otherwise closed when expected to be open, regardless of the state of contactor K2, as a stuck S2 contactor would also be detected upon testing contactor K2, due to their parallel arrangement, although identifying which of the K2 or S2 contactors is stuck would require further investigation.

Diagnostic testing circuit 300 carries out the same sequence for each of the remaining contactors K1, K3, K4. As noted above, the testing sequence is initiated for all contactors K1-K4 at every vehicle start up and shutdown.

Accordingly, the electronic configuration of diagnostic testing circuit 300 enables the ability to determine the operational status of all contactors K1-K4, S2 without any noticeable delays during EV startup, shutdown, or both, while avoiding additional wear on the contactors and the associated energy loss incurred to switch them.

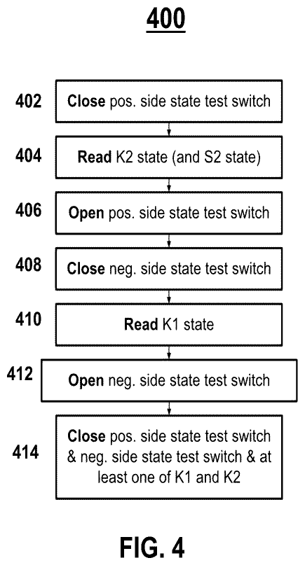

With this said, FIG. 4 illustrates an exemplary process 400 of the diagnostic testing mode for contactors K1 and K2, as enabled by the diagnostic testing circuit 300 configuration, in accordance with the non-limiting embodiments of the present technology.

By way of overview, process 400 commences before a control command to close or after a control command to open contactors K1 and K2 is instructed by the BMS 240 control unit, which typically occurs upon enabling or shutting off the powertrain. Moreover, step 414 occurs when process 400 is performed subsequent to a command to close the main contactors K1 and K2.

With this said, at task 402, positive side test switch 304 is closed (i.e., the positive side test circuit is connected) and at task 404 the status of contactors K2, S2 (the K2 state) is read from sensor 308. That is, based on whether or not a current flows through sensor 308, process 400 determines whether the expected and observed state of contactors K2, S2 match.

In turn, at task block 406, positive side test switch 304 is opened (i.e., the positive side test circuit is disconnected), at task block 408 negative side test switch 302 is closed (i.e., the negative side test circuit is connected), and at task block 410 the status of contactor K1 (the K1 state) is read from sensor 306. Again, based on whether or not current flows through sensor 308, determines whether the expected and observed state of contactor K1 match. It should be appreciated that the described order of task blocks 402-406 and 408-412 is not intended to be limiting, as the order could be switched and equally effective in accordance with the embodiments. For example, contactor K1 could be tested before contactor K2 and S2, or these could both be tested simultaneously.

Subsequently, at task block 414, performed when process 400 is carried out upon requesting the powertrain be energized (before vehicle use), a diagnostic test of the test circuit itself is carried out. At this step 414, it has already been determined that contactors K1 and K2 are not welded or otherwise stuck together, therefore one or both of them can be freely closed at this point and, correspondingly, one or both of the positive and negative side test circuits are closed to confirm that the circuits correctly detect that the state of K1 and/or K2 are closed.

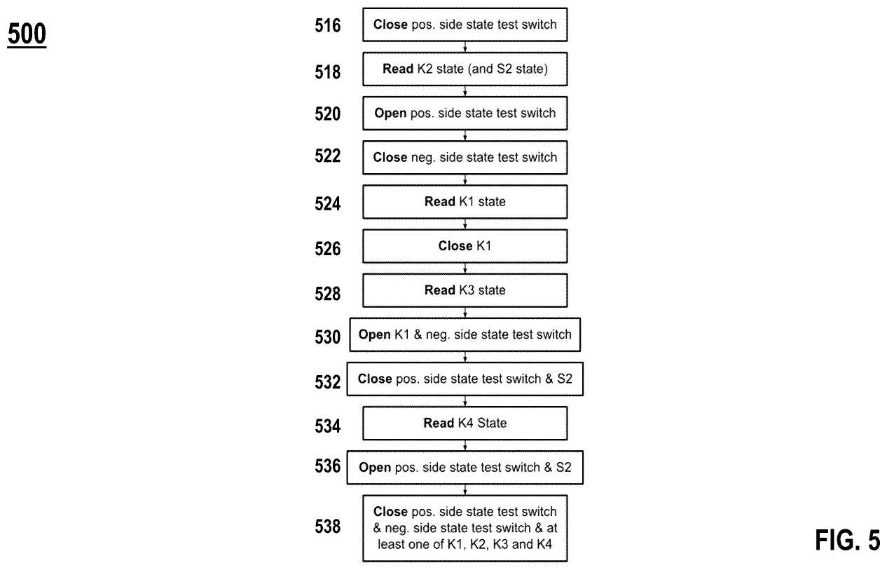

FIG. 5 illustrates an exemplary process 500 of the diagnostic testing mode for contactors K1-K4, as enabled by the diagnostic testing circuit 300 configuration, in accordance with the non-limiting embodiments of the present technology.

Process 500 commences at task block 516, in which positive side test switch 304 is closed and then, at task block 518, the status of contactors K2, S2 is read from sensor 308 to determine whether the expected and observed state of contactors K2, S2 match.

At task block 520, positive side test switch 304 is opened and, at task block 522, negative side test switch 302 is closed. Then, at task block 524, the status of contactor K1 is read from sensor 306 to determine whether the expected and observed state of contactor K1 match.

At task block 526, contactor K1, if step 524 returned a positive match between the expected and observed state of K1, is closed and, at task block 528, the status of fast charge contactor K3 is read from sensor 310 to determine whether the expected and observed state of contactor K3 match.

At task block 530, contactor K1 and negative side test switch 302 are opened and, at task block 532, positive side test switch 304 and pre-charging contactor S2 are closed, assuming step 518 returned a positive match between the expected and observed state of K2/S2. Then at task block 534, the status of fast charge contactor K4 is read from sensor 312 to determine whether the expected and observed state of contactor K4 match. Moreover, as discussed above regarding process 400, the order in which the negative and positive side contactor sets K1-K3 and K2-K4 are tested is not limiting, as the order can be switched with equal effect, in accordance with the disclosed embodiments.

At task block 536, positive side test switch 304 and pre-charging contactor S2 are opened. Also note that, at task block 532, contactor K2 could be closed and subsequently opened at task block 536, instead of contactor S2, since K2 and S2 are in parallel. At task block 538, one or both positive and negative side test switches 302, 304 and anyone, or both, sets of contactors K1-K3 or K2-K4 are closed. This task 538 serves to ensure that the test circuit is functional. Once contactors K1-K4 have been confirmed to not be welded or stuck closed, by performing steps 516-536, any contactor can be safely closed and the expected and observed states are verified as a match.

It will be appreciated that the described sequence order of task blocks 402-414 regarding process 400 and task blocks 516-538 regarding process 500 are exemplary and not, in any way, intended to be limiting, as variations of the sequence order are envisioned as long as the operational status of all contactors K1-K4, S2 are determined during EV startup, before the powertrain circuit is closed or shutdown, after the powertrain circuit has been opened.

In this manner, the disclosed embodiments provide a system and method for determining the operational status of contactors K1-K4, S2 that are configured to handle high voltages/current in order to properly open and close connections to the HV battery pack for EV power operations. Moreover, due the disclosed circuitry, the diagnostic testing of the contactors K1-K4 is performed without needing to actually switch them, reducing wear, energy consumption, or any noticeable delays observed by EV drivers.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed:

1. A system for determining an operational status of at least one contactor of an electric vehicle (EV), the at least one contactor being controllably movable between a closed state and an open state, the system comprising:
an electric power source having a positive and a negative terminal;
a contactor test circuit configured to determine the operational status of the at least one contactor, the contactor test circuit comprising:
at least one test switch electrically-coupled in series with the electric power source, the at least one contactor and at least one sensor, the at least one sensor configured to detect current flow passing therethrough;
a control unit operatively-coupled to the at least one test switch, the at least one contactor, and the at least one sensor, the control unit configured with executable instructions to:
communicate with the at least one contactor to change its current state or receive a signal indicative of its current state;
register an expected state of the at least one contactor, based on the control unit communication or the received signal;
operate the at least one test switch, to detect whether current flows through the at least one sensor;
receive a signal from the at least one sensor indicative of an observed state of the at least one contactor, based on whether current flows through the at least one sensor; and
compare the expected state to the observed state.

2. The system of claim 1, wherein the control unit detecting whether:
current flows through the at least one sensor, indicates that the at least one contactor is in the closed state; and
no current flows through the at least one sensor, indicates that the at least one contactor is in the open state.

3. The system of claim 2 wherein, in response to the comparison indicating that the expected state and the observed state do not match, the control unit issues a warning.

4. The system of claim 1, wherein the at least one sensor comprises an optocoupler.

5. The system of claim 1, wherein the at least one sensor is electrically-coupled in series with a resistor.

6. The system of claim 1, wherein the at least one contactor is electrically-coupled in parallel with a pre-charging contactor and a resistor.

7. The system of claim 1, wherein the at least one sensor and the operations of the at least one test switch are activated by a low voltage signal enabled by the control unit.

8. A method for determining an operational status of at least one contactor of an electric vehicle (EV), the at least one contactor being controllably movable between a closed state and an open state, wherein the EV comprises:
an electric power source with a positive and a negative terminal;
a contactor test circuit configured to determine the operational status of the at least one contactor, the contactor test circuit comprising:
at least one test switch electrically-coupled in series with the electric power source, the at least one contactor and at least one sensor, the at least once sensor configured to detect current flow passing therethrough; and
a control unit operatively-coupled to the at least one test switch, the at least one contactor, and the at least one sensor, the control unit configured with executable instructions to implement the method comprising:
communicating with the at least one contactor to change its current state or receive a signal indicative of its current state;
registering, by the control unit, an expected state of the at least one contactor based on the control unit's communication or the received signal;
operating, by the control unit, the at least one test switch to detect whether current flows through the at least one sensor;
receiving, by the control unit, a signal from the at least one sensor indicative of an observed state of the at least one contactor based on whether current flows through the at least one sensor; and
comparing, by the control unit, the expected state to the observed state.

9. The method of claim 8, wherein the control unit initiates the method by enabling a low voltage activation signal to be forwarded to the at least one sensor and the at least one test switch.

10. The method of claim 8, wherein the control unit detecting whether:
current flows through the at least one sensor, indicates that the at least one contactor is in the closed state; and
no current flows through the at least one sensor, indicates that the at least one contactor is in the open state.

11. The method of claim 8 wherein, in response to the comparison indicating that the expected state and the observed state do not match, issuing a warning.

12. The method of claim 8, wherein:
the at least one test switch further comprises a positive side test switch and a negative side test switch;
the at least one contactor comprises a first contactor associated with the negative terminal of the electric power source and a second contactor associated with the positive terminal of the electric power source;
the at least one sensor comprises:
a first sensor electrically-coupled in series with the electric power source, the negative test switch and the first contactor; and
a second sensor electrically-coupled in series with the electric power source, the positive test switch and the second contactor;
the method further comprising:
closing the positive side test switch to receive a signal from the second sensor to determine an observed state of the second contactor based on whether current flows through the second sensor; and
closing the negative side test switch to receive a signal from the first sensor to determine an observed state of the first contactor based on whether current flows through the first sensor.

13. The method of claim 12, wherein the positive side test switch and the negative side test switch comprise an optocoupler-based switch.

14. The method of claim 12, wherein:
the at least one contactor further comprises a third contactor associated with the negative terminal and a fourth contactor associated with the positive terminal;
the at least one sensor further comprises:
a third sensor, electrically-coupled in series with the electric power source, the negative test switch, the first contactor and the third contactor; and
a fourth sensor, electrically-coupled in series with the electric power source, the positive test switch, the second contactor and the fourth contactor;
the method further comprising:
prior to receiving a signal from the third sensor indicative of an observed state of the third contactor, based on whether current flows through the third sensor, communicating with the first contactor to change its state to the closed state;
prior to receiving a signal from the fourth sensor indicative of an observed state of the fourth contactor, based on whether current flows through the fourth sensor, communicating with the second contactor to change its state to the closed state.

15. The method of claim 14, wherein the control unit detecting whether:
current flows through the first or second sensor, indicates that the corresponding first or second contactor is in the closed state;
current flows through the third sensor, indicates that the first and third contactors are both in the closed state;
current flows through the fourth sensor, indicates that the second and fourth contactors are both in the closed state;
no current flows through the first or second sensor, indicates that the corresponding first or second contactor is in the open state;
no current flows through the third sensor, indicates that one or both of the first and third contactors are in the open state; and
no current flows through the fourth sensor, indicates that one or both of the second and fourth contactors are in the open state.

16. The method of claim 14, wherein in response to the comparisons indicating that the expected state and the observed state of the corresponding contactor or another corresponding contactor do not match, the control unit issues a warning.

17. The method of claim 14, wherein the positive and negative test switches comprise an optocoupler-based switch.

18. The method of claim 14, wherein each of the first, second, third, and fourth sensors comprise an optocoupler.

19. The method of claim 14, wherein each of the first, second, third, and fourth sensors are electrically-coupled in series with corresponding resistors.

20. The method of claim 14, wherein each of the positive and negative test switches and the first, second, third, and fourth sensors are activated by a low voltage signal enabled by the control unit.
